(19) United States
(12) Patent Application Publication
(10) Pub. No.: US 2021/0254241 A1
(43) Pub. Date: Aug. 19, 2021

(54) METHOD FOR RECYCLING SUBSTRATE, METHOD FOR MANUFACTURING SEMICONDUCTOR DEVICE, AND SEMICONDUCTOR DEVICE

(71) Applicant: KYOCERA Corporation, Kyoto-shi (JP)

(72) Inventor: Takeshi KAMIKAWA, Santa Barbara, CA (US)

(73) Assignee: KYOCERA Corporation, Kyoto-shi (JP)

(21) Appl. No.: 16/790,963

(22) Filed: Feb. 14, 2020

(51) Int. Cl. C30B 33/00; H01L 33/00; C30B 25/18; C30B 23/02; C30B 29/40; C30B 7/10; H01L 21/02

(52) U.S. Cl. CPC C30B 33/00; H01L 33/0075; H01L 33/0079; H01L 21/0237; C30B 23/02; C30B 29/406; C30B 7/10; C30B 25/18

(57) ABSTRACT

A substrate recycling method according to the present disclosure is intended for allowing reuse of a first processed substrate obtained by detaching a semiconductor device layer formed on a growth substrate. The substrate recycling method includes a first recycling process of, when the first processed substrate has a thickness greater than a predetermined thickness, polishing a surface of the first processed substrate and obtaining the growth substrate, and a second recycling process of, when the first processed substrate has a thickness less than the predetermined thickness, forming a substrate reclamation layer on the first processed substrate, and polishing a surface of the substrate reclamation layer and obtaining the growth substrate.

### BACKGROUND OF THE INVENTION

### 1. Field of the Invention

The present invention relates to a method for recycling a substrate, a method for manufacturing a semiconductor device, and a semiconductor device.

### 2. Description of the Related Art

A nitride semiconductor represented by GaN, AlN, InN and mixed crystals thereof has a larger bandgap (Eg), as compared to an AlGaInAs-based semiconductor and an AlGaInP-based semiconductor, and also has a feature of a direct transition-type material. For this reason, the nitride semiconductor attracts attention, as a material configuring a semiconductor light-emitting device such as a semiconductor laser device capable of emitting light in wavelength regions ranging from ultraviolet to green, a light-emitting diode device capable of covering wide light-emitting wavelength ranges from ultraviolet to red, and the like, and wide application to a projector, a full-color display, environment and medical fields, and the like is considered.

In recent years, the technology trend shifts from a hetero-epitaxial growth technology of forming a film of nitride semiconductor on a heterogeneous substrate (sapphire, Si, SiC) to a homo-epitaxial growth technology of forming a nitride semiconductor on the same nitride semiconductor substrate. This is because, in the hetero-epitaxial growth technology, many defects that deteriorate device characteristics, such as dislocations and stacking faults, occur at an epitaxial interface with the substrate, with the consequent difficulties in characteristic improvement.

Unfortunately, the nitride semiconductor substrate is very expensive, and has thus not been applied to a low-priced product such as an LED (light emitting device). Typical examples of heretofore suggested substrate manufacturing methods include a hydride vapor phase epitaxy (HVPE) method, an ammonothermal method, and a Na flux method. Although these methods have succeeded in achieving a certain degree of reduction in substrate price, there is still room for improvement.

The inventors have analyzed the reason why the manufacture of the nitride semiconductor substrate is costly in the following manner. In the processes of manufacturing a GaN substrate and making the same into a device, a variety of wastes of the substrate and raw materials are generated. That is, to obtain the GaN device, about 90% of the raw materials is discarded, and the remainder, namely about 10% of them is used as a bulk material. However, there arises a 50% material loss in a wafer slicing process, followed by further 75% material loss in a device production process. After all, only about 1.25% of the GaN substrate material will be left for the semiconductor device.

Thus, the semiconductor device is manufactured with a significant wastage that dominates the costs of the substrate and the device, and hinders price reduction. It is important how to reduce the wastage, and, the reduction of the significant wastage affords remarkable advantageous effects such as a reduction in CO₂ emission entailed by the production, power saving, and a reduction in raw materials in use. This can greatly reduce the load applied to the global environment.

A plurality of methods for detaching a semiconductor device layer from a nitride semiconductor substrate have been proposed (for example, refer to Japanese Unexamined Patent Publication JP-A-2006-332681 (Patent Literature 1)). However, there is no disclosure of a method of reclaiming a substrate after the detachment of a semiconductor device layer. Actually, the substrate recycling has not been implemented, and there is no known effective substrate recycling method.

As described above, the expensiveness of the nitride semiconductor substrate may lead to an increase in the cost of manufacture of a semiconductor device using the nitride semiconductor substrate.

An object of the invention is to provide a highly efficient substrate recycling method for recycling a nitride semiconductor substrate, a semiconductor device manufacturing method, and a semiconductor device.

### SUMMARY OF THE INVENTION

A substrate recycling method according to the present disclosure for allowing reuse of a first processed substrate obtained by detaching a semiconductor device layer formed on a growth substrate, includes: a first recycling process of, when the first processed substrate has a thickness greater than a predetermined thickness, polishing a surface of the first processed substrate and obtaining a second processed substrate which reaches a state where the semiconductor device layer can be formed on a surface of the second processed substrate, and can serve as the growth substrate; and a second recycling process of, when the first processed substrate has a thickness less than the predetermined thickness, forming a substrate reclamation layer on the first processed substrate, and polishing a surface of the substrate reclamation layer and obtaining a third processed substrate which reaches a state where the semiconductor device layer can be formed on a surface of the third processed substrate, and can serve as the growth substrate.

A semiconductor device manufacturing method according to the present disclosure includes: growing a semiconductor device layer on the second processed substrate or the third processed substrate as described above; and detaching the semiconductor device layer.

A semiconductor device according to the present disclosure is manufactured by the semiconductor device manufacturing method as described above.

### BRIEF DESCRIPTION OF THE DRAWINGS

Other and further objects, features and advantages of the invention will be more explicit from the following detailed description taken with reference to the drawings wherein:

FIG. 1 is a flow chart showing an example of a substrate recycling method according to the present disclosure;

FIG. 2A is an explanatory drawing of a first recycling process;

FIG. 2B is an explanatory drawing of the first recycling process;

FIG. 3 is a pictorial view showing an example of an HVPE apparatus that effects a growth process using an HVPE method;

FIG. 4A is an explanatory sectional view of a kerf loss;

FIG. 4B is an explanatory sectional view of the kerf loss;

FIG. 4C is an explanatory sectional view of the kerf loss;

FIG. 5 is a sectional view showing an example of a nitride semiconductor device layer;

FIG. 6A is a sectional view showing a semiconductor device manufacturing method according to an example of the present embodiment;

FIG. 6B is a sectional view showing the semiconductor device manufacturing method according to an example of the present embodiment;

FIG. 7A is a sectional view showing the semiconductor device manufacturing method according to an example of the present embodiment;

FIG. 7B is a sectional view showing the semiconductor device manufacturing method according to an example of the present embodiment;

FIG. 7C is a sectional view showing the semiconductor device manufacturing method according to an example of the present embodiment;

FIG. 8A is a sectional view showing the semiconductor device manufacturing method according to an example of the present embodiment;

FIG. 8B is a sectional view showing the semiconductor device manufacturing method according to an example of the present embodiment;

FIG. 9A is a sectional view showing the semiconductor device manufacturing method according to an example of the present embodiment;

FIG. 9B is a sectional view showing the semiconductor device manufacturing method according to an example of the present embodiment; and

FIG. 9C is a sectional view showing the semiconductor device manufacturing method according to an example of the present embodiment.

### DETAILED DESCRIPTION

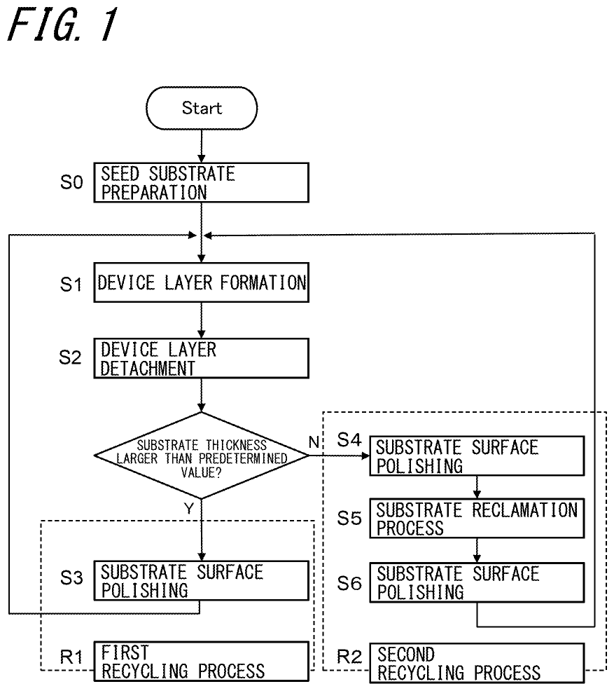

The inventors thought a recycling method having a high raw material efficiency, as a method of recycling a substrate, considering reducing a unit price of the substrate. In this case, the inventors conceived a recycling technology in which the waste is uniformly generated in each process and the improvement on the waste is carried out in all processes, considering waste reduction. In the present disclosure, a two-step recycling is considered for the substrate recycling. The following describes the details of preferred embodiments of the invention with reference to the drawings. FIG. 1 is a flow chart showing an example of a substrate recycling method according to the present disclosure.

First, there is performed a preparation step of preparing a seed substrate which can be used as a growth substrate, on a principal surface of which a semiconductor device layer is to be formed. That is, in the preparation step S0, there is prepared a seed substrate of a nitride semiconductor such as gallium nitride (GaN) or aluminum nitride (AlN). A surface of the nitride semiconductor seed prepared has been already subjected to pre-processing, such as surface-damaged layer removing and planarization, for enabling growth.

In general, slicing, outer shape processing, surface polishing, etc., which are normally performed, may be carried out. One of the methods may be selectively used or a combination thereof may be used. When the methods are used in combination, the methods may be performed in order of slicing, outer shape processing, and surface polishing. Each processing is described in detail. For example, the slicing may be performed by cutting a semiconductor crystal ingot by a wire. The outer shape processing means making a shape of the substrate into a circular or rectangular form. Dicing, outer periphery polishing, wire cutting method, and the like may be exemplified. As the surface polishing, a method of polishing a surface by using abrasive grains such as diamond abrasive grains, CMP (chemical mechanical polishing), damaged layer etching by RIE (Reactive Ion Etching) after mechanical polishing, and the like may be exemplified.

A surface roughness, such for example as a root-mean-square roughness (Rms) measured by an atomic force microscope, of a growth substrate is preferably 1.0 nm or less, more preferably 0.5 nm, or most preferably 0.3 nm. Also, in the specification, for regrowth or device layer formation, the substrate already subjected to the CMP processing is preferably used upon the planarization of the substrate surface and the removal of the damaged layer, as described above.

Subsequently, in a device layer forming step S1, a semiconductor device layer is formed on the growth substrate. That is, the semiconductor device layer is formed on the growth substrate by means of MOCVD or otherwise in a film formation apparatus. In the device layer forming step S1, films of an n-type semiconductor layer, an active layer, a p-type semiconductor layer, etc. are formed by a film formation apparatus. After that, a wafer is taken out from the film formation apparatus, and is then subjected to general device processes such as p-electrode formation, n-electrode formation, protective film formation, etc., to constitute a device structure.

Subsequently, in a detaching step S2, the semiconductor device layer is detached from the growth substrate. There are a variety of substrate detachment methods, which will be described in detail later. The detached semiconductor device layer is subjected to a general device mounting process so as to become a device module. Following the detachment of the semiconductor device layer, the remaining growth substrate will be referred to as a first processed substrate.

The first processed substrate, which has been obtained via the first round of the detaching step S2 to remove the semiconductor device layer, still has a thickness large enough for reuse, and is thus subjected to a first recycling process R1 where the surface of the substrate is suitably treated for reuse. In the first recycling process R1, outer shape processing and surface polishing process as described above are performed on the first processed substrate to obtain a second processed substrate. In a growth surface reclamation step S3, the first processed substrate is worked into the second processed substrate which is reused as a growth substrate. Subsequently, a semiconductor device layer is formed on the substrate in the device layer forming step S1. Then, the semiconductor device layer is detached in the detaching step S2, thus forming the first processed substrate. While the thickness of the first processed substrate to be formed is reduced whenever the first recycling process R1 is repeated, as long as the thickness of the first processed substrate is greater than a predetermined set substrate thickness, the first recycling process is repeated.

When the thickness of the first processed substrate obtained via the detaching step S2 reaches the predetermined set substrate thickness via the first recycling process R1 at least one or more times, then a second recycling process is performed. In the second recycling process R2, a growth surface reclamation step S4 is performed first. The conditions set for the substrate surface polishing process in the growth surface reclamation step S4 may be the same as or may be different from the conditions set for the growth surface reclamation step S3.

After the surface processing as seed for regrowth of the surface of the first processed substrate is performed in the growth surface reclamation step S4, a substrate reclamation step S5 is performed. In the substrate reclamation step S5, the first processed substrate is carried and arranged into a regrowth apparatus, and, re-formation of a substrate reclamation layer having a thickness of about 80 μm to 2000 μm is performed on the substrate by a film formation method such as the HVPE method, the ammonothermal method, the MOCVD method, etc. The substrate reclamation layer may be formed of the same semiconductor material as that constituting the surface of the substrate.

After the formation of the substrate reclamation layer is over, in the substrate reclamation step S5, the substrate having the substrate reclamation layer is taken out from the regrowth apparatus, and is subjected to a growth surface reclamation step S6. In the growth surface reclamation step S6, the first processed substrate having the substrate reclamation layer undergoes outer shape processing and surface polishing processing so as to obtain a surface state where a semiconductor device layer can be formed by the MOCVD method. Then, the second recycling process R2 comes to an end. That is, in the second recycling process R2, the first processed substrate is successively subjected to the growth surface reclamation step S4, the substrate reclamation step S5, and the growth surface reclamation step S6 to obtain a third processed substrate. The third processed substrate can be used as a growth substrate for forming a semiconductor device layer.

Following the completion of the second recycling process R2, the third processed substrate is used as a growth substrate in the device layer forming step S1. In the device layer forming step S1, an n-type semiconductor layer, an active layer, a p-type semiconductor layer, etc. are film-formed by means of MOCVD or otherwise. After the MOCVD operation, the wafer is taken out, and is subjected to general device processes such as p-electrode formation, n-electrode formation, protective film formation, etc., to form a semiconductor device layer. Then, the semiconductor device layer is detached in the detaching step S2.

After that, depending on the thickness of the first processed substrate obtained via the detaching step S2, the first recycling process R1 or the second recycling process R2 is performed to reclaim the first processed substrate obtained via the detaching step S2 as the second processed substrate or the third processed substrate. This permits repetitive use of a single substrate as a growth substrate.

<First Recycling Process>

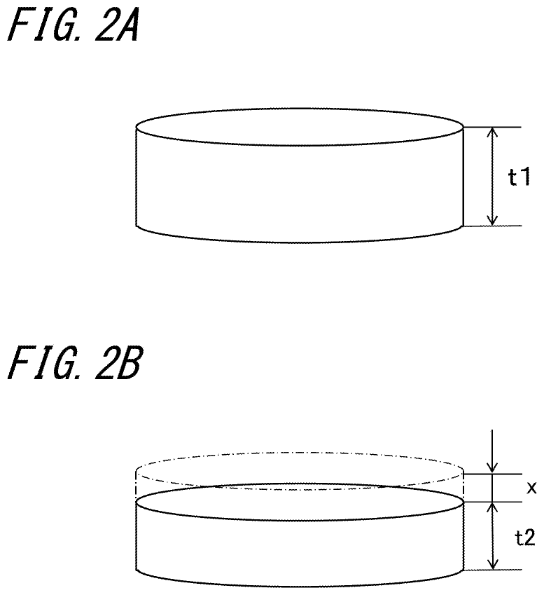

The following describes the details of the first recycling process R1. Following the completion of layer detachment, the first processed substrate is subjected to the first recycling process R1. In the first processed substrate which has just undergone the detachment of the semiconductor device layer, the substrate surface is damaged, or a detached part has an unevenness shape due to the film formation by the MOCVD method upon the formation of the device, the electrode vapor deposition upon the device process, the etching process, etc. The substrate having such a surface state may be difficult to regrow. For this reason, in the growth surface reclamation step S3, the first processed substrate is subjected to surface polishing operation that includes re-polishing of the first processed substrate after the detachment and removal of attached impurities and particles to eliminate the surface unevenness. This makes it possible to accomplish the device layer forming step S1 satisfactorily. In the growth surface reclamation step S3, normally, the surface of the first processed substrate is polished by about 10 to 100 μm, so that the substrate surface can be planarized and the damaged layer can be removed. The extent of reduction of thickness caused by the growth surface reclamation step S3 is defined as a surface polishing thickness x. That is, as shown in FIGS. 2A and 2B, after the first recycling process R1, the first processed substrate has a thickness t2 which is smaller than the initial substrate thickness t1 thereof by an amount corresponding to the surface polishing thickness x. The substrate thickness is reduced by an amount corresponding to the surface polishing thickness x whenever the first recycling process R1 is repeated.

The second processed substrate is obtained via the growth surface reclamation step S3. As a growth substrate, the second processed substrate is again subjected to the device layer forming step S1 where a semiconductor device layer is formed on the substrate surface by means of MOCVD or otherwise. After that, the semiconductor device layer is detached from the growth substrate. After the layer detachment, the substrate is, as the first processed substrate, again subjected to the first recycling process R1 which includes the growth surface reclamation step S3. In this way, as the first recycling process R1 is repetitively performed, the first processed substrate is gradually thinned. Given that the number of times the first recycling process R1 is repeated until such time that the procedure proceeds to the second recycling process R2 is A, then the layer thickness t₁ₛₜ of the first processed substrate immediately before the initiation of the second recycling process R2 is expressed in equation form as: t₁ₛₜ=t1−A×x.

As the result of repetition of the first recycling process R1 after the second recycling process R2, a reclaimed film thickness t_{R2} of the film formed in the second recycling process R2 is exceeded (t_{R2}≤A×x), which may cause uncovering of the surface of the seed substrate. In this case, the surface state of the film produced in the substrate reclamation step S5 and the surface state of the seed substrate are not the same in a strict sense, because the formation processes are different. Therefore, the optimal condition of the film formation start is not satisfied upon the film formation by the MOCVD method in the subsequent device layer forming step S1. For this reason, it is preferable that a reclaimed film thickness t_{R2}, which is the thickness of the film re-formed in the substrate reclamation step S5 during the second recycling process R2, is greater than the film thickness to be reduced in the first recycling process R1 to be thereafter performed (t_{R2}≥A×x).

<Second Recycling Process>

The following describes the details of the second recycling process R2. The first processed substrate, now having a thickness less than or equal to the predetermined thickness after undergoing the repeated (at least one time) first recycling process R1, is subjected to the growth surface reclamation step S4 in the second recycling process R2. In this step, surface polishing is performed to form a growth surface for reclamation of the substrate. After that, the third processed substrate is obtained via the substrate reclamation step S5 and the growth surface reclamation step S6. The third processed substrate is, as a growth substrate, subjected to the semiconductor device layer forming step S1 and the detaching step S2. After the detaching step S2, the substrate is, as the first processed substrate, again subjected to the first recycling process R1 or the second recycling process R2. Thus, a single substrate can be continuously reused as long as it is not damaged due to any reason.

The use of the invention makes it possible to minimize the waste of the substrate, and thereby allow a high-quality device produced on the free standing GaN substrate by homo-epitaxial growth to be manufactured at very low cost.

For example, it is preferable that the thickness of the film re-formed in the substrate reclamation step S5 during the second recycling process R2, viz., the reclaimed film thickness t_{R2}, is greater than the film thickness to be reduced (A×x) in the first recycling process R1 to be thereafter repeated (t_{R2}≥A×x). Thereby, even when the second recycling process R2 is repeated, it is possible to keep the entire substrate thickness, as well as to protect the substrate from fracture during handling and renders the substrate less prone to fracture under the influence of strain resulting from the thermal cycle upon the re-formation.

In the alternative, the first recycling process is repeated several times, and, after stopping the work under conditions where the relationship of t_{R2}≥A×x holds, the first processed substrate is again subjected to the growth surface reclamation step S4 prior to the substrate reclamation step S5 in the second recycling process R2. In the growth surface reclamation step S4, the surface of the first processed substrate is further polished so that the substrate surface comes below the original level of the surface of the seed substrate to uncover the semiconductor at the surface of the seed substrate, and, a nitride semiconductor thin film is formed in the substrate reclamation step S5. In this case, in each and every substrate reclamation step S5, the plane appearing on the substrate surface is a surface of the seed substrate. This makes it possible to improve the quality of the substrate reclamation layer formed by growth operation in the substrate reclamation step S5, and thereby obtain a high-quality third processed substrate. The use of this third processed substrate as a growth substrate enables the semiconductor device to be produced with a higher yield.

In the substrate reclamation step S5 of the second recycling process R2, the substrate reclamation layer may be formed by the ammonothermal method or the HVPE method. Note that any other method that enables formation of a nitride semiconductor layer on the nitride semiconductor substrate may be entirely satisfactory. The following description deals with the case where the substrate reclamation layer is formed by the representative ammonothermal method and HVPE method. These methods are general methods for crystal growth of the nitride semiconductor. The growth conditions are disclosed in many documents, and the film formation may be performed using the conditions.

The following describes regrowth technique based on the ammonothermal method and the HVPE method. Note that any other method that enables re-formation of a nitride semiconductor on the nitride semiconductor seed substrate, such as the MOCVD method or MBE (Molecular Beam Epitaxy), may be entirely satisfactory.

<Ammonothermal Method>

The following describes the ammonothermal method. In the ammonothermal method, an autoclave made of nickel-based alloy is used as a pressure-resistant container and a capsule made of Pt—Ir is used as a reaction container for crystal growth. The polycrystalline GaN particles, which are a raw material, are arranged in a lower region (raw material melting region) of the capsule, and high-purity NH₄F and the like may be used as mineralizer. The c-plane substrate obtained by the HVPE method is arranged in a furnace, and a seed substrate of which surface has been subjected to the CMP method is used. The film formation rate is generally about 200 to 300 μm/day.

In the general ammonothermal method, as the mineralizer, one or more compositions including fluorine may be exemplified. As the composition, hydrogen fluoride (HF), ammonium fluoride (NH₄F), ammonium acid fluoride (NH₅F₂), gallium fluoride (GaF₃) and diamine complex thereof (GaF₃.2NH₃) and ammonium hexafluorogallate ((NH₄)₃GaF₆) may be exemplified.

Further, fluorine (F), hydrogen (H), nitrogen (N), and gallium (Ga), or a reaction products of metal, ammonia, and fluorine hydrogen may be included as the mineralizer. Moreover, as the mineralizer, a plurality of substances may be selected from among the above-described compositions and reaction products. In the mineralizer, a total content of oxygen in the mineralizer composition is less than about 100 ppm by weight. Also, a mineralizer composition including at least one fluorine and at least one chlorine, bromine or iodine may be used. The mineralizer is appropriately adjusted so that a bulk nitride semiconductor having desired crystallinity is to be obtained. During the film formation, the processing is performed in supercritical ammonia at a temperature of 400° C. or higher and at a pressure of about 100 MPa or higher in the container.

<HVPE Method>

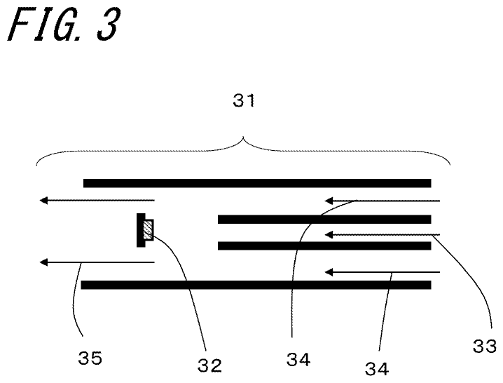

FIG. 3 is a pictorial view showing a HVPE apparatus that performs a growth process using the HVPE method. As the HVPE apparatus, a manufacturing apparatus for Group-III nitride semiconductor (hereinafter, referred to as ‘manufacturing apparatus’) is exemplified. In the manufacturing apparatus 31, it is general to spray a Group-III gas 33 including Group-III chloride (GaCl, AlCl, InCl, etc.) and a Group-V gas 34 including NH₃ to a substrate (underlying substrate) 32 at the same time. By this method, it is possible to implement the high-speed growth of several 100 μm/hour. A general method of generating the Group-III gas 33 includes providing a region of 800° C. or higher in the manufacturing apparatus 71, arranging a Group-III raw material (Ga, Al, In, etc. in a metal state, not shown) in the region, and introducing a HCl gas or a Cl₂ gas therein to generate Group-III chloride. Moreover, a path from a Group-III chloride generation place to a crystal growth region is also maintained at the temperature of 800° C. or higher so as to suppress precipitation of the Group-III chloride. Preferably, the path is maintained at a temperature of about 1000° C. An exhaust gas 35 which has passed through the substrate 32 is processed outside the HVPE apparatus.

As conditions of a raw material and a flow rate, for example, as the Group-III gas 33, a Group-III chloride-containing gas including GaCl set at 100 ccm, H₂ set at 1000 ccm, and N₂ set at 1900 ccm in terms of flow rate, is used, and, as the Group-V gas 34, a NH₃-containing gas including NH₃ set for 1000 ccm and N₂ set for 2000 ccm in terms of flow rate is used. The temperature of the substrate 32 (i.e., the temperature of the tip portion of GaN crystal) is set at 1100° C. For the substrate 32 which becomes seed crystals, as a GaN substrate to be recycled, a free standing GaN substrate having a thickness of 800 μm is used for regrowth in the second recycling process R2. The conditions are not so limited, and may be appropriately changed so as to obtain desired crystals.

<Initial Substrate Thickness t1>

As described above, in the first recycling process R1, the substrate thickness is reduced from the initial substrate thickness t1 by an amount corresponding to the surface polishing thickness x whenever the corresponding step is repeated. A substrate thickness of a free standing GaN substrate that is currently distributed as a commercial product is about 300 μm to 450 μm. The following is the reason. When the GaN substrate is made thick, there are advantages, for example, the substrate is difficult to be fractured upon the handling, or the substrate is less bent upon the film formation by the MOCVD method, which leads to higher yield. However, the cost increases. To the contrary, when the GaN substrate is made thin, the cost decreases, but there are disadvantages, for example, the substrate is susceptible to the fracture, or the substrate may be bent upon the film formation by the MOCVD method, which leads to lower yield. Considering the cost, it is required to make the substrate thickness as thin as possible, and a thickness of the limit thereof is the above-described substrate thickness.

During the normal semiconductor device manufacturing, as a final step, multiple semiconductor device chips are sliced from the substrate. However, at this time, in a state of the wafer, the substrate is thinned by performing grinding and polishing until the substrate thickness reaches 100 μm or less. Thereby, it is possible to easily divide the substrate into the chips and to improve the yield upon the division. It is known that the chip division in the thickness of 100 μm or greater lowers the yield. In this way, the substrate thickness that finally remains in the device is 100 μm or less, and the remnant is discarded. That is, even when the initial substrate thickness is 600 μm or 300 μm, it finally becomes 100 μm or less and the substrate is then divided into the semiconductor device chips. Therefore, most of the thick substrate is wasted and discarded. This corresponds to a 75% loss of the GaN substrate upon the device manufacturing process shown in FIG. 10. Furthermore, the time required to process the thick substrate to 100 μm or less increases, which leads to an increase in the process cost, and also an increase in the equipment investment. Thus, a thick substrate is not used under normal circumstances.

However, the thick substrate has the advantages, for example, the substrate is difficult to be fractured upon the handling, or the substrate is less bent upon the film formation by the MOCVD method. Thus, there is a tradeoff relation between the cost and the advantage of the thick substrate, and it is difficult to satisfy both at the same time. In this regard, in the present disclosure, the recycling is premised, and the device is detached. Therefore, it is not necessary to divide the substrate for chip division. For this reason, it is not necessary to thin the growth substrate, so that there occurs no problem even when the growth substrate is thick. Further, in the substrate reclamation step S5 of the second recycling process R2, the substrate is less prone to warpage, and is also less prone to fracture caused by the strain resulting from the thermal cycle during the process. Meanwhile, it has been found out that, when using a thin substrate, under application of very strong force, such as mechanical stress resulting from surface polishing operation in the substrate reclamation step S5, the substrate suffers from fracture, and consequently the yield is considerably lowered.

In particular, as the first recycling process R1 is repeated, the thickness of the substrate is gradually reduced. Therefore, when the initial substrate thickness t1 reaches about 300 μm, like the usual substrate, for example, as the first recycling process R1 is repeated three times, the thickness may be less than 200 μm. When the substrate reaches such thickness, the fracture is likely to occur, so that the yield is remarkably lowered. For this reason, when performing the second recycling process, as is the case with the present disclosure, the initial substrate thickness t1 prior to recycling process, viz., the thickness of the substrate that is yet to be subjected to the first recycling process R1 and the second recycling process R2, is preferably greater than or equal to 500 μm (t1≥500 μm), or more preferably greater than or equal to 600 μm (t1≥600 μm) from the standpoint of yield improvement upon the regrowth.

Moreover, as the advantages of using the thick film substrate, for example, in the case where the process starts with the substrate having the thin thickness of 300 μm, when the substrate is thinned in the first recycling process R1, and the substrate thickness becomes 200 μm, then the film thickness of the growth substrate accounts for 67% of the initial thickness. When the film is formed by the MOCVD method, the thinning ratio of the growth substrate is so high that the thermal capacity of the growth substrate is reduced, with the consequent increase of variation in surface temperature. Although an approach to this problem may be made by effecting adjustment to the heating and cooling conditions, too large a difference in temperature makes it very difficult to cope with the problem, and consequently the yield may be lowered.

However, for example, in the case of using the substrate having a substrate thickness of 1000 μm, even when the thickness of the growth substrate is reduced to 900 μm as the result of repetition of the first recycling process R1, the substrate thickness still constitutes 90% of the initial thickness, and thus, variation in thermal capacity can be greatly reduced. The temperature difference of the growth substrate surface (difference in temperature between the case for the substrate thickness of 1000 μm and the case for the substrate thickness of 900 μm) can be reduced, as compared to the case where the initial thickness of the substrate is small. In addition to such an additional advantage, the use of the thick substrate can render a temperature distribution within the plane of the growth substrate uniform. The recycling of the thick substrate for its reuse makes it possible to obtain the advantage inherent to the thick growth substrate upon the film formation by the MOCVD method.

As described above, although the use of the thick growth substrate results in the high cost, like the invention, the recycling permits cost reduction even with use of the thick substrate. Thus, the two-step recycling including the first recycling process R1 and the second recycling process R2 using the thick-film substrate can overcome the cost disadvantage of the thick-film substrate. This cost advantage and the superiority of the thick substrate cancel out the described tradeoff relation.

<Kerf Loss-Free>

The advantageous feature of the present disclosure is that the two-step recycling permits kerf loss-free substrate reclamation, that is; achieves elimination of kerf loss that is to be generated in substrate wafer slicing operation.

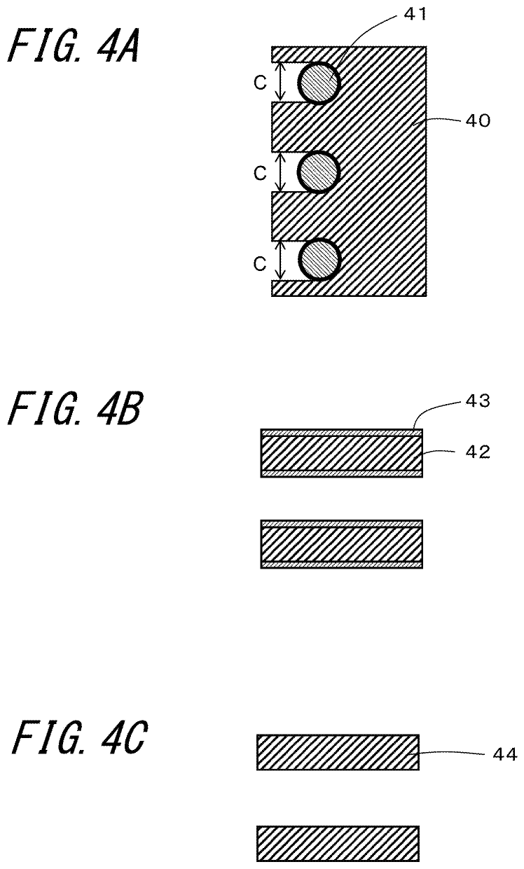

The kerf loss is briefly described with reference to FIGS. 4A to 4C. The nitride semiconductor substrate is formed to have a thickness of 10 μm or greater by a nitride semiconductor film formation apparatus using the HVPE method, the ammonothermal method or otherwise. The nitride semiconductor substrate is finally sliced into a nitride semiconductor substrate having a substrate thickness of about 300 to 400 μm. At this time, as shown in FIG. 4A, a bulk 40 is usually cut with a wire saw. When slicing a substrate from the bulk 40, a part of the bulk which corresponds to the diameter c of a wire 41 of the wire saw is cut, and any cut pieces go to waste. For this reason, the diameter of the wire 41 of the wire saw is made to be small. However, as shown in FIG. 4B, considering a saw damaged layer 43 constituting the surface of the sliced substrate 42, almost a half of the bulk 40 is finally cut due to the kerf loss and subsequent removal of the saw damaged layer 43. In consequence, only about a half of the substrate remains as a usable substrate 44 as shown in FIG. 4C. The kerf loss is causative of an increase in unit price of the substrate.

Regarding the kerf loss and the saw damage, it is possible to completely reduce the waste upon the manufacturing of the substrate by reducing the kerf loss by the change in thinking of reducing a thickness of the layer to be formed in the second recycling process R2 to thereby obtain one substrate from one seed (usually, a plurality of substrates is obtained from one seed).

After the second recycling process R2, the substrate is simply subjected to the surface planarization and the substrate shaping processing, so that it can be reused as a substrate. Therefore, it is possible to considerably reduce the number of processes, the process time, the labor cost and the like. Also, the effect of the recycled substrate to be repetitively used is very high because a substrate having a low defect density and a substrate having a small in-plane distribution of an off angle can be selectively used and such a high-quality substrate can be repetitively used to repeatedly manufacture the high-quality chip with the stable yield. This is one of the very excellent points of the present disclosure, and the industrial availability thereof is very great.

<Plane Orientation of Substrate>

A principal surface of the substrate such as the nitride semiconductor substrate or the nitride semiconductor seed substrate is a principal surface that is to be used for formation of the nitride semiconductor device or epitaxial growth of GaN crystal, and is finished to a planar surface from which the damaged layer has been removed, so as to suit the purpose. The plane orientation of the substrate is not particularly limited, and an index plane parallel or nearly parallel with the principal surface may be an m-plane, an a-plane, a c-plane, a {30-31} plane, a {30-3-1} plane, a {20-21} plane, a {20-2-1} plane, a {30-32} plane, a {30-3-2} plane, a {10-11} plane, a {10-1-1} plane, a {11-22} plane, etc.

In a preferable example, the surface of the substrate has an angle of 0 to 30° relative to the m-plane. Further, in the specification, the “m-plane” is a non-polar plane comprehensively represented as a {1-100} plane, a {01-10} plane, a {−1010} plane, a {−1100} plane, a {0-110} plane and a {10-10} plane, and specifically, means a (1-100) plane, a (01-10) plane, a (−1010) plane, a (−1100) plane, a (0-110) plane and a (10-10) plane. Also, in the specification, the “a-plane” is a non-polar plane comprehensively represented as a {2-1-10} plane, a {−12-10} plane, a {−1-120} plane, a {−2110} plane, a {1-210} plane and a {11-20} plane, and specifically, means a (2-1-10) plane, a (−12-10) plane, a (−1-120) plane, a (−2110) plane, a (1-210) plane and a (11-20) plane. In the specification, the “c-axis”, “m-axis” and “a-axis” mean axes perpendicular to the c-plane, the m-plane, and the a-plane, respectively. Also, in the specification, the “off angle” means an angle indicative of deviation of any plane from an index plane. In the specification, the “tilt angle” means an angle indicating how much the crystal axis at other position on the principal surface deviates from the crystal axis at a center, on the basis of the crystal axis at the center of the principal surface of the crystal plane.

<Nitride Semiconductor Seed Substrate>

For the nitride semiconductor seed substrate, gallium nitride (GaN), indium gallium nitride (InGaN), aluminum gallium nitride (AlGaN), aluminum nitride (AlN) and the like can be used. Further, as the seed substrate that is used for the crystal growth of the invention, substrates manufactured by various methods can be used. In the case of the usual device mass production, the most commonly used substrates are those that can be mass-produced by the HVPE method or otherwise. However, when the nitride semiconductor seed substrate is repetitively used, as is the case with the present disclosure, it is possible to produce the device even though the nitride semiconductor seed substrate is manufactured by an expensive method with which it is not possible to perform the mass production or a method with which it is difficult to perform the mass production.

In the substrate recycling method and the semiconductor device element according to the present disclosure, it is important to use a substrate having high crystallinity and in-plane uniformity, as the nitride semiconductor seed substrate. In this case, the nitride semiconductor seed substrate may be manufactured by a method capable of manufacturing such a substrate, which is also one advantage of the present disclosure. The manufacturing cost of the seed substrate can be reduced by the recycling. Therefore, it is possible to sufficiently use a method that could not be applied to the mass production of the device because it is possible to manufacture the substrate having high crystallinity and in-plane uniformity of characteristics by the method but the production cost thereof is high. Also, since the substrate having high in-plane uniformity is repetitively used, there is also an advantage that the device with high yield can be produced all the time.

For example, regarding the manufacturing method of the nitride semiconductor seed substrate, a substrate manufactured by an ammonothermal method capable of manufacturing a substrate having high crystallinity and in-plane uniformity and less susceptible to the bending, or a substrate manufactured by a Na flux method capable of manufacturing a substrate having a low defect density may be used. The HVPE method that has been conventionally used may also be used. Also, the substrate manufacturing methods may be used in combination. For example, a substrate manufactured by forming a bulk nitride semiconductor on a nitride semiconductor substrate having a low defect density, which is manufactured by the Na flux method, with the HVPE method and then slicing the same may be used as the nitride semiconductor seed substrate of the invention, or a substrate manufactured by forming a bulk nitride semiconductor on a nitride semiconductor substrate, which is manufactured by the HVPE method, with the ammonothermal method and then slicing the same may be used as the nitride semiconductor seed substrate of the invention.

As an example, a single crystal manufactured by the ammonothermal method and a crystal obtained by cutting the signal crystal may be preferably used. The crystal manufactured by the ammonothermal method can be preferably used as the nitride semiconductor seed substrate because it can grow a favorable nitride crystal in which strain is reduced and an in-plane distribution of the defect density and an in-plane distribution of the tilt angle are small. The nitride semiconductor seed substrate manufactured by the HVPE method can also be used for the present disclosure without any problem.

<Preparation of Nitride Semiconductor Seed Substrate>

Here, as an example, a method of producing a c-plane GaN substrate from a bulk nitride semiconductor on a sapphire substrate by the HVPE method, slicing a plurality of underlying substrates from the bulk nitride semiconductor so that the m-plane is to be the principal surface, and forming a gallium nitride crystal of which the principal surface is the m-plane on the sliced substrate by the ammonothermal method is described.

First, gallium nitride (GaN) was grown on a sapphire substrate by the metalorganic chemical vapor deposition (MOCVD) method. A GaN template of which the principal surface is the c-plane was prepared by non-doping, a Si₃M₄ mask was formed above the template, and a c-plane-GaN layer was grown by the epitaxial lateral overgrowth through openings of the mask, so that a seed substrate was prepared. Then, the seed substrate was arranged on the susceptor so that the c-plane-GaN layer thereof was exposed to the upper surface by using the HVPE apparatus. Then, the temperature of the reaction chamber was increased to 1000° C., for example, and the GaN single crystal was grown. In the growth process, the film formation conditions such as film formation pressure are exemplified. The growth pressure was about 1×10⁵ Pa, the partial pressure of GaCl gas was about 6×10² Pa, and the partial pressure of NH₃ gas was about 8×10³ Pa. The growth time was 100 hours. After the growth was over, the temperature was lowered to the room temperature to obtain GaN single crystal. The GaN single crystal of which the thickness was 10 mm and the principal surface was the C-plane could be obtained on the seed substrate.

Here, the obtained C-plane-GaN single crystal was sliced to obtain a plane having off angles of 0° in the [0001] direction and 0° in the [−12-10] direction from the (10-10) plane, so that a plurality of small piece substrates were obtained. Among them, a single crystal GaN (free standing) having a rectangular shape of long side 50 mm×short side 5 mm and a thickness of 330 μm was prepared as the underlying substrate. Among the underlying substrates manufactured as described above, single crystal GaN having a rectangular shape of long side 20 mm×short side 10 mm and a thickness of 330 μm may be used as the underlying substrate, and the nitride crystal may be grown on the underlying substrate by the ammonothermal method or the HVPE method. By using the above method, it is possible to obtain the gallium nitride crystal of which the principal surface is the m-plane.

A plurality of plate-shaped crystals of which the principal surface is the m-plane were cut from the obtained gallium nitride crystal, the front and back surfaces and four sides of the m-plane, which is the principal surface, were etched to remove the damage, and the front and back surfaces of the m-plane were further mirror-polished, so that it is possible to obtain a GaN crystal of which the principal surface is the m-plane.

Also, the GaN single crystal of which the principal surface is the c-plane may be sliced, and the sliced crystal may be directly used as the nitride semiconductor substrate of the c-plane, and a variety of methods are also considered. However, the invention is not particularly limited with respect to the manufacturing method of the nitride semiconductor seed. More specifically, as described above, the single crystal manufactured by the ammonothermal method and the crystal obtained by cutting the signal crystal may be preferably used.

<Nitride Semiconductor Layer>

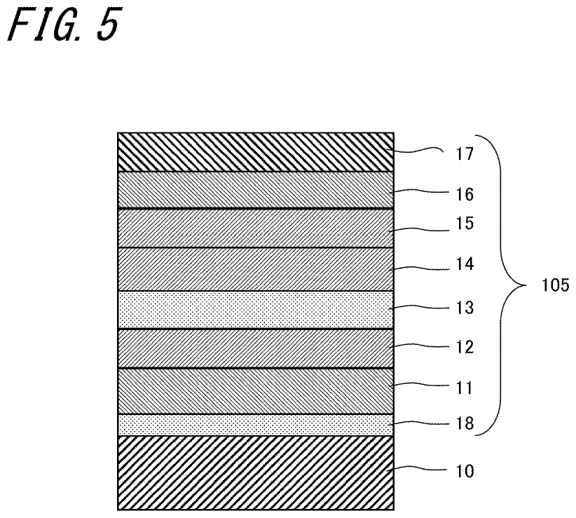

Here, an example of the nitride semiconductor device layer, which is formed on the substrate by the MOCVD method or otherwise, is shown in FIG. 5. A nitride semiconductor device layer 105 is formed as a semiconductor laser structure on a GaN substrate 10. A lower clad layer 11 composed of n-type Al_{0.06}Ga_{0.94}N and having a thickness of about 2.2 μm is formed. Also, on the lower clad layer 11, a lower guide layer 12 composed of n-type Al_{0.005}Ga_{0.995}N and having a thickness of about 0.1 μm is formed. On the lower guide layer 12, an active layer is formed. The active layer 13 has a quantum well (DQW; Double Quantum Well) structure in which two well layers composed of Inₓ₁Ga₁₋ₓ₁N and three barrier layers composed of Alₓ₂Ga₁₋ₓ₂N are alternately stacked.

Also, on the active layer 13, a carrier block layer 14 composed of p-type Al_{y}Ga_{1-y}N and having a thickness of 40 nm or smaller (for example, about 12 nm) is formed. The carrier block layer 14 is configured so that an Al compositional ratio y thereof is 0.2. Also, on the carrier block layer 14, an upper guide layer 15 composed of p-type Al_{0.01}Ga_{0.99}N is formed. The upper guide layer 15 is configured so that the Al compositional ratio is smaller than the clad layer. Also, on a convex part of the upper guide layer 15, an upper clad layer 16 composed of p-type Al_{0.06}Ga_{0.94}N and having a thickness of about 0.5 μm is formed. On the upper clad layer 16, a contact layer 17 composed of p-type Al_{0.01}Ga_{0.99}N and having a thickness of about 0.1 μm is formed. As an example, it is possible to form a semiconductor device layer having the layer structure as described above. Here, the semiconductor laser structure as described above is exemplified but an LED or an electronic device structure is also possible. Any device having a separable structure can be used.

For example, when a PEC (photoelectrochemical) method of using the PEC methods and a sacrificial layer to detach the nitride semiconductor layer (device layer) from the nitride semiconductor substrate by using the PEC methods and a sacrificial layer is used as a substrate detaching process, a sacrificial layer 18 (for example, 5 nm-thick In_{0.3}Ga_{0.7}N layer) may be formed upon the formation of the semiconductor device layer by the MOCVD method. In the detaching step S2 of removing the semiconductor device layer, the detachment layer is selectively etched by an alkali etchant such as KOH and irradiation of light having a wavelength that is to be absorbed by the sacrificial layer, so that the device can be detached. As the substrate, a (0001) plane (c-plane)-oriented free standing GaN substrate is used. The substrate measures 2 inches in diameter.

<Nitride Semiconductor Layer Detaching Method>

The several methods have been reported as the detaching method of the nitride semiconductor layer. In the invention, the nitride semiconductor substrate may be preferably detached from the nitride semiconductor layer. For example, as reported in Non-Patent Literature 1 “Phys. Status Solidi B 254, No. 8, 1600774 (2017)” and Non-Patent Literature 2 “Applied Physics Express 9. 056502 (2016)”, the PEC method and the sacrificial layer are used to detach the nitride semiconductor layer (device layer) from the nitride semiconductor substrate. Also, as reported in Non-Patent Literature 3 “J. Phys. D: Appl. Phys. (2016) 315105”, after a ZnO intermediate layer is grown on a GaN substrate, a GaN semiconductor layer is formed on the ZnO intermediate layer by the MOVPE method, and the intermediate layer is etched, so that the nitride semiconductor layer is detached. By using the technologies, it is possible to detach the nitride semiconductor layer from the nitride semiconductor substrate.

Also, as described in Non-Patent Literature 4 “Applied Physics Express, Volume 6, Number 11”, an LED is manufactured on the nitride semiconductor substrate, a Ni thick film (25 μm) is then formed, a part of the GaN substrate is detached using tensile stress of Ni, and at the same time, the LED device layer formed on the nitride semiconductor substrate is entirely detached. Actually, it is possible to detach the device layer from the nitride semiconductor substrate. The invention is not influenced by the detaching method, and the substrate can be reused by removing the damaged layer of the surface unless the substrate is largely damaged due to the detachment and cannot be thus reused. Since the depth of the damaged layer is different depending on the detaching method, it is necessary to optimize the polishing thickness upon the re-polishing, depending on the detaching method.

### Embodiment 1

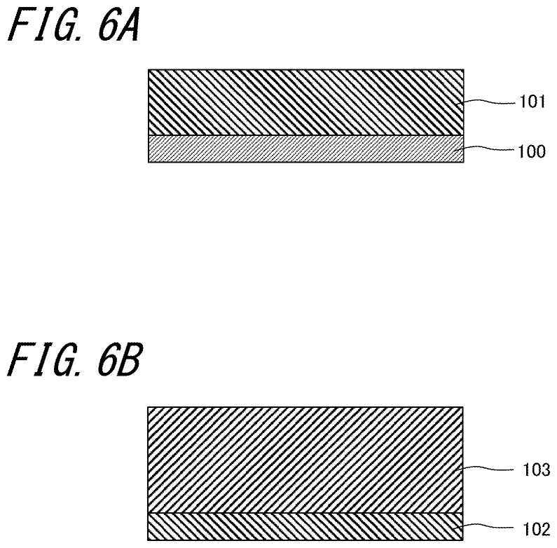

The specific embodiments of the invention are described. FIGS. 6A to 9C are sectional views showing a semiconductor device manufacturing method according to an example of the present embodiment. In the present embodiment, for the nitride semiconductor seed substrate, a GaN substrate 104 having a c-plane growth surface is used. The GaN substrate 104 is produces by the ammonothermal method. Also, the second recycling process R2 is performed by the HVPE method. In the below, the specific method is described.

The following describes the method of obtaining the GaN substrate 104 as the nitride semiconductor seed substrate in the preparation step S0. As shown in FIG. 6A, on a sapphire substrate 100, a GaN thick film having a thickness of about 5 to 10 mm is formed by the HVPE method to obtain bulk GaN 101. Then, a free standing GaN substrate 102 is formed by performing slicing in a direction parallel to the c-plane. The free standing GaN substrate 102 has a thickness of about 300 μm to 1200 μm.

Further, after that, as shown in FIG. 6B, the free standing GaN substrate 102 manufactured by the HVPE method is, as the seed substrate, subjected to the growth in the direction of the c-plane by the ammonothermal method, so that bulk GaN crystal 103 formed by the ammonothermal method can be obtained. Then, the slicing, the outer shape processing, the surface polishing and the like, which are normally performed, may be performed. One of the methods may be selectively used or a combination thereof may be used. When the methods are used in combination, the methods may be performed in order of the slicing, the outer shape processing and the surface polishing. Each processing is described in detail. The slicing may be performed by wire cutting, for example. The outer shape processing means making a shape of the substrate into a circular or rectangular form, and dicing, outer periphery polishing, wire cutting method and the like may be exemplified. Examples of the surface polishing may include a method of polishing a surface by using abrasive grains such as diamond abrasive grains, the CMP method, and a damaged layer etching method by RIE method after mechanical polishing.

The bulk GaN crystal 103 is again sliced in parallel with the c-plane, so that the c-plane GaN substrate 104 formed by the ammonothermal method can be obtained. At this time, it is possible to obtain the c-plane GaN substrate having a thickness of 800 μm by controlling a slicing interval and adjusting a polishing amount and a CMP amount.

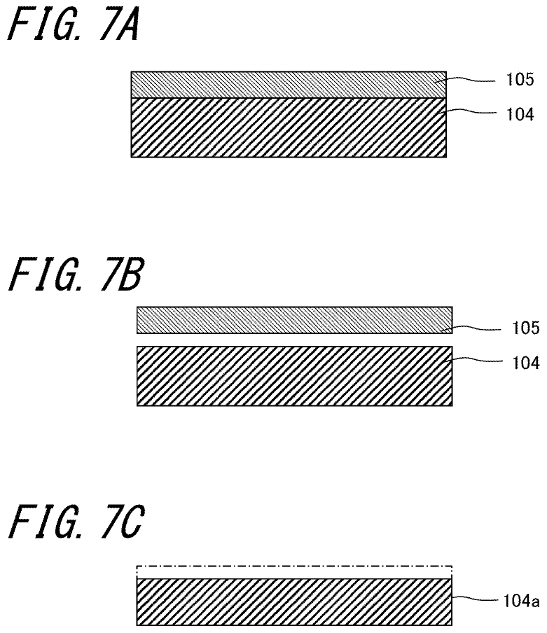

In the preparation step S0, the surface treatment on the surface for the growth of the device layer has been completed. The device layer forming step S1 is performed by the MOCVD method. The following description deals with the case of using the 800 μm-thick GaN substrate 104. As shown in FIG. 7A, on the GaN substrate 104, for example, a nitride semiconductor device layer 105 as described above is formed by the MOCVD method (this is a general method and the description thereof is omitted).

Then, the procedure proceeds to the detaching step S2. The detachment is performed by one of the above-described methods. As shown in FIG. 7B, the PEC (Photo-Electro Chemical) method is used to detach the nitride semiconductor device layer 105 by the dry etching method. By the dry etching method, the sacrificial layer 18 shown in FIG. 5 is exposed and is then selectively etched in a solution of potassium hydroxide (KOH), so that the nitride semiconductor device layer 105 can be detached from the GaN substrate 104.

Next, the first recycling process R1 is performed. As shown in FIG. 7C, following the completion of the detaching step S2, the GaN substrate 104 is subjected to the growth surface reclamation step S3 to remove the damaged layer generated on the substrate surface due to the detachment of the nitride semiconductor device layer 105. To begin with, the GaN substrate 104 is polished by an amount of about 50 μm to remove the damaged layer. Subsequently, to increase the flatness of the surface, as a growth substrate obtained by reclamation process via polishing operation using the CMP method, a GaN substrate 104a is further formed, whereupon the first recycling process R1 comes to an end.

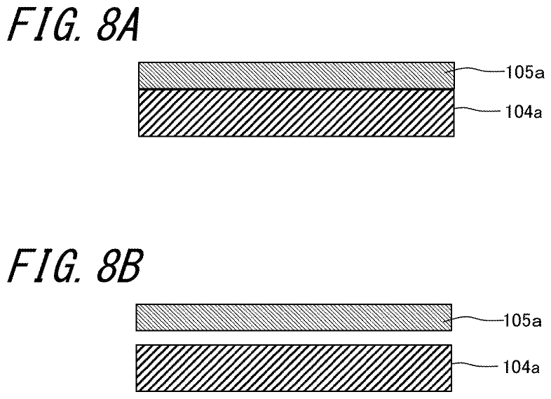

Next, as shown in FIG. 8A, in the device layer forming step S1, a nitride semiconductor device layer 105a is formed on the GaN substrate 104a obtained as a reclaimed growth substrate. Then, as shown in FIG. 8B, the detaching step S2 is performed once again. After that, the first recycling process may be repeated more than once, and, the procedure may proceed to the growth surface reclamation step S6 in the second recycling process R2. The following description deals with the case where the first recycling process R1 is repeated four times to obtain a GaN substrate 104b which is thinned by a total of 200 μm through polishing operation via the four first recycling processes R1. That is, prior to proceeding to the second recycling process R2, the GaN substrate 104b has a thickness of 600 μm, which is smaller by 200 μm than the initial substrate thickness set at 800 μm.

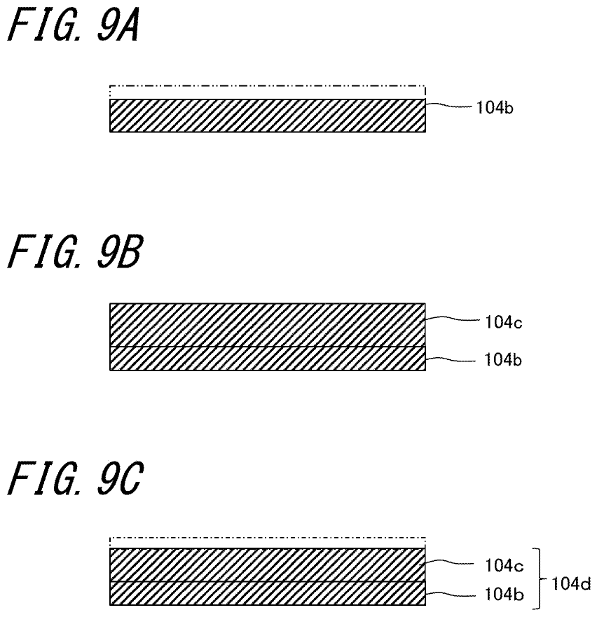

In the second recycling process R2, as shown in FIG. 9A, in the growth surface reclamation step S4, surface polishing is performed for regrowth by the HVPE. At this time, the substrate is further polished by 50 μm, and finally reaches a thickness of 550 μm. Thereafter, as shown in FIG. 9B, the substrate reclamation step S5 is performed. In the substrate reclamation step S5, a 300 μm-thick substrate reclamation layer 104c is formed by the HVPE method. This process can be implemented in the film formation time of no more than 2 hours. A thickness greater than the substrate thickness which is lost during several first recycling processes R1 is reclaimed in the second recycling process R2.

At this point of time, the thickness of the GaN substrate 104b and the substrate reclamation layer 104c stands at 850 μm. Thereafter, for example, to planarize the surface of the substrate, as shown in FIG. 9C, in the growth surface reclamation step S6, the surface of the substrate reclamation layer 104c is ground by about 50 μm in surface grinding operation, and the surface thereof is then trimmed by the CMP method. Thus, a GaN substrate 104d is obtained as a growth substrate.

When the substrate reclamation step S5 of the second recycling process R2 is performed with the HVPE method, it is possible to efficiently reclaim only one side of the substrate. Also, since the growth rate is fast, for example, about 150 μm to 250 μm/h, it is possible to reclaim the substrate thickness to the initial substrate thickness in a very short time. In this way, the GaN substrate 104d serving as the growth substrate can keep the initial substrate thickness and can be repetitively recycled.

The substrate can be regrown to a thickness of 10 mm, for example, in the second recycling process R2. In this case, however, it is necessary to again slice the substrate. In this case, the kerf loss is caused due to the wire saw. With this in view, a reduction in the reclaimed film thickness obtained in the second recycling process R2 makes it possible to eliminate the need for the slicing operation, and thereby achieve kerf loss-free as described above.

As practiced in Embodiment 1, the GaN substrate 104 formed by the ammonothermal method has advantages that its warpage is smaller and the in-plane non-uniformity of the off angle and tilt angle is smaller, as compared to the substrate manufactured by the HVPE method. When using such a GaN substrate 104, the in-plane device characteristic distribution is small upon the formation of the semiconductor device layer by the MOCVD method, so that it is possible to achieve the high yield.

The first object of the re-formation of the semiconductor layer by the second recycling process R2 is to reclaim the substrate thinned in the first recycling process R1. That is, the first object is to suppress the unintentional fracture of the substrate, which is caused when the substrate whose thickness is gradually reduced by repetition of the first recycling process R1 is continuously used, and to increase the number of reclamation times of the substrate. Also, the substrate is thickened, so that upon the formation of the semiconductor device layer by the MOCVD, the warpage due to the strain, which is caused by the difference in substrate thermal expansion coefficients or the like, is suppressed and the in-plane non-uniformity of the composition and impurity concentration distribution of the substrate are suppressed. In particular, when the InGaN layer is included in the semiconductor device layer, since the In composition is sensitive to the temperature, it is highly advantageous to use the thick film substrate that can be stably temperature-controlled. This was not preferable because the using of the thick film substrate in the usual device production, in which the recycling is not premised, simply results in the increase in cost of the substrate. However, it is possible to solve the tradeoff problem of the low cost and yield of the substrate by the application of the present disclosure.

For the GaN substrate 104 as the nitride seed substrate, the polar plane (c-plane), the non-polar plane (m-plane, a-plane), and the {30-31}, {30-3-1}, {20-21}, {20-2-1}, {10-11}, {10-1-1}, {10-11}, {10-1-1}, {10-12}, {10-1-2}, {11-22} and {11-2-2} planes as the semipolar substrate may be used.

According to the present disclosure, in the course of manufacture from the beginning of the nitride semiconductor substrate production process to the completion of the nitride semiconductor device production process, it is possible to effectively improve the raw material efficiency in the production of the bulk nitride semiconductor, and to reduce the wastes (kerf loss, etc.) in the production of the nitride semiconductor substrate, with the consequent savings in the costs of the nitride semiconductor substrate and the nitride semiconductor device element produced from the nitride semiconductor substrate.

### Embodiment 2

In Embodiment 2, for the nitride semiconductor seed substrate, the m-plane GaN substrate (not shown) was used and the nitride semiconductor seed substrate was manufactured by the ammonothermal method. Also, the second recycling process was performed by the HVPE method.

When using the non-polar substrate represented by the m-plane and the a-plane or the semipolar plane substrate other than the c-plane (as the semipolar substrate, the {30-31}, {30-3-1}, {20-21}, {20-2-1}, {10-11}, {10-1-1}, {10-11}, {10-1-1}, {10-12}, {10-1-2}, {11-22} and {11-2-2} planes may be exemplified), the substrate can be regrown to a thickness of 10 mm, for example, in the second recycling process R2. In this case, however, it is known that the basal plane stacking defect existing in the nitride semiconductor seed substrate increases, so that the defect density increases. In this case, when the reclaimed film thickness in the second recycling process R2 is suppressed to 600 μm or less, or preferably 400 μm or less, it is possible to suppress the increase in the basal plane stacking defect, thereby suppressing the increase in the defect density. Regarding the substrate reclamation step S5, the same step as that described in Embodiment 1 can be performed.

### Embodiment 3

In the present embodiment, for the nitride semiconductor seed substrate, the c-plane GaN substrate (not shown) was used, and the nitride semiconductor seed substrate was manufactured by the ammonothermal method. Moreover, in the second recycling process R2, the substrate reclamation step S5 was performed by the ammonothermal method. It is possible to manufacture the high-quality substrate having less strain.

### Embodiment 4

In the present embodiment, for the nitride semiconductor seed substrate, the c-plane GaN substrate (not shown) was used, and the nitride semiconductor seed substrate was manufactured by the HVPE method. Moreover, the amount of polishing in the first recycling process was reduced to 10 μm or less, so that the second recycling process R2 was performed by means of MOCVD at a low film-formation rate. That is, the substrate reclamation step S5 was performed by the MOCVD method. In this case, a high-quality substrate having less strain can be produced, and, the use of MOCVD for the second recycling process R2 permits greater improvement in regrowth yield than does the use of other method. By virtue of the advantageous effects thus obtained, such as the reduction of occurrence of particles within the plane of the substrate, the improvement of in-plane crystal quality distribution, and the reduction of abnormal growth regions, substrate reclamation can be achieved with high yield in the second recycling process R2.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A substrate recycling method for allowing reuse of a first processed substrate obtained by detaching a semiconductor device layer formed on a growth substrate, comprising:
a first recycling process of, when the first processed substrate has a thickness greater than a predetermined thickness, polishing a surface of the first processed substrate and obtaining a second processed substrate which reaches a state where the semiconductor device layer can be formed on a surface of the second processed substrate, and can serve as the growth substrate; and
a second recycling process of, when the first processed substrate has a thickness less than the predetermined thickness, forming a substrate reclamation layer on the first processed substrate, and polishing a surface of the substrate reclamation layer and obtaining a third processed substrate which reaches a state where the semiconductor device layer can be formed on a surface of the third processed substrate, and can serve as the growth substrate.

2. The substrate recycling method according to claim 1, wherein a thickness of the substrate reclamation layer formed in the second recycling process is greater than a layer thickness to be reduced in the first recycling process.

3. The substrate recycling method according to claim 1, wherein a hydride vapor phase epitaxy method is used in the second recycling process.

4. The substrate recycling method according to claim 1, wherein an ammonothermal method is used in the second recycling process.

5. The substrate recycling method according to claim 1, wherein an MOCVD method is used in the second recycling process.

6. The substrate recycling method according to claim 1, wherein an initial thickness of an initial substrate prior to recycling is greater than or equal to 500 μm.

7. The substrate recycling method according to claim 1, wherein slicing of the substrate reclamation layer is not performed after the second recycling process.

8. A semiconductor device manufacturing method, comprising:
growing the semiconductor device layer on the second processed substrate or the third processed substrate according to claim 1; and
detaching the semiconductor device layer.

9. A semiconductor device manufactured by a semiconductor device manufacturing method according to claim 8.
